(19) United States
(12) Patent Application Publication
(10) Pub. No.: US 2023/0357635 A1
(43) Pub. Date: Nov. 9, 2023

(54) SILICON ETCHANT AND SILICON ETCHING METHOD

(71) Applicant: TOKYO OHKA KOGYO CO., LTD., Kawasaki-shi (JP)

(72) Inventor: YaChien Chuang, Kawasaki-shi (KR)

(21) Appl. No.: 18/191,652

(22) Filed: Mar. 28, 2023

(30) Foreign Application Priority Data
Mar. 31, 2022 (TW) 111112402

(51) Int. Cl. C09K 13/00

(52) U.S. Cl. CPC C09K 13/00

(57) ABSTRACT

A silicon etchant, containing a quaternary ammonium hydroxide, an amine, and a solvent, in which the amine is a polyamine and/or an alkanolamine.

### BACKGROUND OF THE INVENTION

### Field of the Invention

The present invention relates to a silicon etchant for manufacturing various silicon devices and a silicon etching method.

Priority is claimed on Taiwanese Pat. Application No. 111112402, filed in Taiwan on Mar. 31, 2022, the content of which is incorporated herein by reference.

### Description of Related Art

A technology for miniaturizing semiconductor devices has enabled the densification of functional units in the semiconductor devices. For example, a reduction in the size of a transistor enables the incorporation of more memory elements on a chip and results in the production of a product with an increased capacity.

In a case of manufacturing a semiconductor device by subjecting a silicon-on-insulator substrate (hereinafter, may be referred to as a “silicon substrate”) having a functional film layer such as a silicon oxide film (SiOx) or a silicon nitride film (SiN), to an etching treatment, an alkaline etchant is used in most manufacturing processes in consideration of etching selectivity. The selectivity refers to the property of exhibiting particularly high etchability with respect to a specific member. For example, in a case where a silicon substrate having a silicon film and another film (for example, SiOx, SiN, or the like) is etched, it is said in general that the selectivity to silicon is high in a case where only the silicon film is etched and the other film is not etched.

In a method of carrying out silicon-anisotropic etching with an alkaline etchant in the related art, an alkaline aqueous solution containing potassium hydroxide (KOH), sodium hydroxide (NaOH), a quaternary ammonium hydroxide (for example, tetramethylammonium hydroxide (TMAH)), or the like is used, and a silicon-anisotropic etchant containing a quaternary ammonium hydroxide is suitably used from the viewpoint that no metal is contained.

For example, Patent Document 1 discloses an etchant for removing a part or all of a polycrystalline silicon film or an amorphous silicon film, where the silicon etchant contains an alkali compound, an oxidizing agent, a hydrofluoric acid compound, and water, the alkali compound being potassium hydroxide, ammonia, or quaternary ammonium hydroxide, and makes it possible to form a cylinder structure in which the aspect ratio of the patterned shape is 15 to 100.

In addition, Patent Document 2 discloses a mixed liquid containing quaternary ammonium hydroxide and water, which is a silicon etchant containing a compound such as ethylene glycol monopropyl ether, ethylene glycol dimethyl ether, diethylene glycol monomethyl ether, or the like, which is represented by Formula (1) R¹O-(CₘH₂ₘO)ₙ-R² (in the formula, R¹ is a hydrogen atom or an alkyl group having 1 to 3 carbon atoms, R² is a hydrogen atom or an alkyl group having 1 to 6 carbon atoms, m is an integer of 2 to 6, and n is 1 or 2).

### Citation List

### Patent Documents

[Patent Document 1] Japanese Unexamined Pat. Application, First Publication No. 2013-135081

[Patent Document 2] Japanese Unexamined Pat. Application, First Publication No. 2020-126997

### SUMMARY OF THE INVENTION

Among the quaternary ammonium hydroxides, tetramethylammonium hydroxide is a common chemical used in silicon etching in the field of manufacturing microelectronic devices. However, with the improvement of the domestic occupational safety and health act in Taiwan, a law revision of the law called “Ordinance on Prevention of Hazards Due to Specified Chemical Substances”, which has been proclaimed on Sep. 16, 2021, lists tetramethylammonium hydroxide is as a class C First Substance and specify a limitation of the amount (2.38% by weight or less in terms of a mixture) in order to prevent health hazards caused by workers inhaling specific chemical gases, vapors, or dust in the workplace. However, in a case where the amount is reduced to the legal standard, the etching ability of such a small amount of tetramethylammonium hydroxide is insufficient.

In addition, with the miniaturization of semiconductor devices, in a case of carrying out silicon etching with respect to such a narrow space having a high aspect ratio, it is necessary to add a surfactant to an etchant in order to increase the permeability of the etchant. However, the addition of the surfactant also drastically reduces the silicon etching rate (the Si etching rate).

The present invention has been made in consideration of the above circumstances, and an object of the present invention is to provide a silicon etchant having a high etching rate and having a low surface tension and a small contact angle with respect to a substrate, and a silicon etching method for a silicon substrate having a high aspect ratio, in which an etching treatment is carried out with the silicon etchant.

Due to legal regulations in Taiwan, the amount of tetramethylammonium hydroxide in an etchant mixture is necessary to be 2.38% by weight or less, it is not possible to increase the silicon etching rate by increasing the amount of tetramethylammonium hydroxide. In addition, a conventional strong alkali such as potassium hydroxide, sodium hydroxide, or the like is also unsuitable for miniaturization in the field of microelectronic devices due to concerns about residual metals, and thus it is also not possible to increase the silicon etching rate with a conventional strong alkali. In contrast, the inventors of the present invention found that the above problems can be solved by using a combination of a strongly basic amine selected from the group consisting of a polyamine and an alkanolamine, and tetramethylammonium hydroxide, and furthermore, by adding a specific surfactant, thereby completing the present invention.

That is, the present invention includes the following contents.
. A silicon etchant, including:
   a component (A): a quaternary ammonium hydroxide;
   a component (B): amines; and
   a component (C): a solvent,
   in which the component (B) is at least one or more selected from the group consisting of a polyamine and an alkanolamine.
. The silicon etchant according to [1], in which the component (B) is at least one or more selected from the group consisting of 1,3-propanediamine, ethylenediamine, 1,2-propanediamine, 1,4-butanediamine, 2-(2-aminoethoxy)ethanol, and diisopropanolamine.
. The silicon etchant according to [1] or [2], in which the component (B) is 1,3-propanediamine or diisopropanolamine.
. The silicon etchant according to [1], in which the component (A) is tetramethylammonium hydroxide.
. The silicon etchant according to [1], in which the component (C) is at least one or more selected from the group consisting of water and a water-soluble organic solvent.
. The silicon etchant according to [5], in which the component (C) is water.
. The silicon etchant according to [1], in which a content of the component (A) is more than 0% by weight and 2.38% by weight or less with respect to a total weight of the silicon etchant.
. The silicon etchant according to [1], in which a content of the component (B) is more than 0% by weight and 30% by weight or less with respect to a total weight of the silicon etchant.
. The silicon etchant according to [1], further containing a component (D): a surfactant.
. The silicon etchant according to [9], in which a content of the component (D) is 0% by weight or more and 1% by weight or less with respect to a total weight of the silicon etchant.
. The silicon etchant according to [9] or [10], in which the component (D) is an anionic surfactant.
. A silicon etching method including subjecting a silicon substrate having a silicon layer with an aspect ratio of 50 or more to an etching treatment using the silicon etchant according to any one of [1] to [11].
. The silicon etching method according to [12], in which the silicon substrate has a silicon layer with an aspect ratio of 200 or less.
. The silicon etching method according to [12], in which a contact angle between the silicon etchant and the silicon substrate is less than 35°.
. The silicon etching method according to [12], in which a surface tension between the silicon etchant and the silicon substrate is less than 35 mN/m.

According to the present invention, it is possible to provide a silicon etchant having a high etching rate and having a low surface tension and a small contact angle with respect to a substrate, and a silicon etching method for a silicon substrate having an aspect ratio, in which an etching treatment is carried out with the silicon etchant.

### BRIEF DESCRIPTION OF THE DRAWINGS

FIG. 1A shows a silicon substrate before an etching treatment.

FIG. 1B shows a silicon substrate after an etching treatment.

### DETAILED DESCRIPTION OF THE INVENTION

### Silicon Etchant

A silicon etchant according to a first aspect of the present invention contains a component (A): a quaternary ammonium hydroxide; and a component (B): amines; and a component (C): a solvent, which the component (B) is at least one or more selected from the group consisting of a polyamine and an alkanolamine.

### <Component (A)>

In the silicon etchant of the present embodiment, various quaternary ammonium hydroxides in the related art, which are used as components of silicon etchants, are used as the quaternary ammonium hydroxide, which is the component (A). The quaternary ammonium hydroxide is generally represented by NR₄⁺OH⁻, where R generally represents a monovalent hydrocarbon group, and the four R’s may be the same or different.

Examples of the monovalent hydrocarbon group include a monovalent linear or branched alkyl group, a monovalent linear or branched alkenyl group, a monovalent alicyclic hydrocarbon group, and a monovalent aromatic hydrocarbon group.

Examples of the linear alkyl group include linear alkyl groups having 1 to 20 carbon atoms, such as a methyl group, an ethyl group, a propyl group, a butyl group, and a pentyl group.

Examples of the branched alkyl group include branched alkyl groups having 3 to 20 carbon atoms, such as a 1-methylethyl group, a 1-methylpropyl group, a 2-methylpropyl group, a 1-methylbutyl group, and a 2-methylbutyl group.

Examples of the linear alkenyl group include a vinyl group, and a propenyl group (an allyl group).

Examples of the branched alkenyl group include a 1-methylvinyl group, a 2-methylvinyl group, a 1-methylpropenyl group, and a 2-methylpropenyl group.

Examples of the monovalent alicyclic hydrocarbon group include monocyclic alicyclic hydrocarbon groups such as a cyclopropyl group, a cyclobutyl group, and a cyclopentyl group, and polycyclic alicyclic hydrocarbon groups obtained by removing one hydrogen atom from polycycloalkanes such as decalin and perhydroazulene.

Examples of the monovalent aromatic hydrocarbon group include a group obtained by removing one hydrogen atom from an aromatic ring. Specific examples of the aromatic ring include aromatic hydrocarbon rings such as benzene, naphthalene, anthracene, and phenanthrene; and aromatic heterocyclic rings obtained by substituting a part of carbon atoms constituting the aromatic hydrocarbon rings with hetero atoms.

Specific examples of the component (A) include tetramethylammonium hydroxide (TMAH), tetraethylammonium hydroxide (TEAH), tetrapropylammonium hydroxide (TPAH), and tetrabutylammonium hydroxide (TBAH), which can be used without any particular limitation.

Among them, tetramethylammonium hydroxide (TMAH) represented by the following structural formula is preferable.

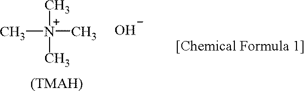

The component (A) contained in the silicon etchant may be used alone or in combination of two or more kinds thereof.

The upper limit value of the content of the component (A) is preferably 2.38% by weight or less with respect to the total weight of the silicon etchant; the lower limit value thereof is more than 0% by weight, preferably 1.0% by weight or more, more preferably 1.2% by weight or more, and still more preferably 1.4% by weight or more, which is not limited thereto.

### <Component (B)>

In the silicon etchant of the present embodiment, the amines, which are the component (B), are at least one or more selected from the group consisting of a polyamine and an alkanolamine.

Examples of the polyamine include various diamine compounds such as ethylenediamine, propylenediamine, tetramethylenediamine, pentamethylenediamine, and hexamethylenediamine. Among them, a diamine compound selected from ethylenediamine (EDA), 1,2-propanediamine (12DAP), 1,3-propanediamine (13DAP), or 1,4-butanediamine (14DAB), each of which is represented by the following structural formula, is preferable, and 1,3-propanediamine is more preferable.

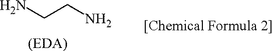

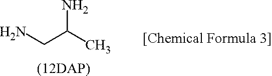

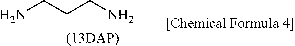

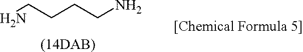

Examples of the alkanolamine include various alkanolamine compounds such as ethanolamine, propanolamine, and butanolamine. Among them, 2-(2-aminoethoxy)ethanol (DGA) or diisopropanolamine (DIPA), each of which is represented by the following structural formula, is preferable, and diisopropanolamine is more preferable.

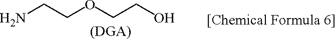

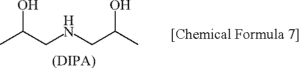

The component (B) contained in the silicon etchant may be used alone or in combination of two or more kinds thereof.

The upper limit value of the content of the component (B) is 30% by weight or less, preferably 25% by weight or less, and more preferably more than 20% by weight, with respect to the total weight of the silicon etchant; the lower limit value thereof is more than 0% by weight, preferably 1% by weight or more, and still more preferably 2% by weight or more, which is not limited thereto.

In a case of containing more than 0% by weight of the component (B) in the silicon etchant, an effect of increasing the silicon etching rate can be obtained. As the content of the component (B) increases, the silicon etching rate generally increases. For example, in the case of the 1,3-propanediamine described above, the silicon etching rate conversely decreases significantly in a case where the content thereof is more than 30% by weight, although the silicon etching rate depends on the kind of amine compound.

### <Component (C)>

The silicon etchant of the present embodiment contains a solvent as the component (C). The component (C) is at least one or more selected from the group consisting of water and a water-soluble organic solvent. The component (C) is preferably water.

As the water, pure water, ion exchange water, or the like can be used.

Examples of the water-soluble organic solvent include an alcohol-based solvent, an ether-based solvent, and a glycol ether-based solvent. One kind of the water-soluble organic solvent may be used alone, or two or more kinds thereof may be used in combination.

Specific examples of the alcohol-based solvent include a monohydric alcohol such as methanol, ethanol, n-propanol, isopropanol, n-butanol, isobutanol, sec-butanol, tert-butanol, n-amyl alcohol, isoamyl alcohol, sec-amyl alcohol, or tert-amyl alcohol; and a polyhydric alcohol such as ethylene glycol, propylene glycol, butanediol, 1,5-pentanediol, 1,6-hexanediol, 1,2-hexanediol, 2,4-hexanediol, hexylene glycol, 1,7-heptanediol, octylene glycol, glycerin, or 1,2,6-hexanetriol.

Specific examples of the ether-based solvent include diisopropyl ether, diisobutyl ether, diisopentyl ether, di-n-butyl ether, di-n-pentyl ether, di-sec-butyl ether, diisopentyl ether, di-sec-pentyl ether, and di-tert-amyl ether.

Specific examples of the glycol ether-based solvent include ethylene glycol monomethyl ether, ethylene glycol monoethyl ether, ethylene glycol monobutyl ether, diethylene glycol monomethyl ether, diethylene glycol monoethyl ether, diethylene glycol monopropyl ether, and diethylene glycol monobutyl ether.

The content of the component (C) is not particularly limited. The content of the component (C) is typically the amount remaining in the silicon etchant, with respect to component (A), the component (B), and a component (D) which will be described later.

### <<Component (D)>>

The silicon etchant of the present embodiment may further contain a component (D): a surfactant, in addition to the component (A), the component (B), and the component (C).

Any surfactants of various anionic, cationic, or nonionic surfactants can be used as the surfactant, which is the component (D); however, among them, an anionic surfactant is preferable. The anionic surfactant is preferably an alkylsulfonic acid salt, and specifically, Takesurf-A-32-Q (manufactured by TAKEMOTO OIL & FAT Co., Ltd.) is more preferable.

In a case where the component (D) is contained in the silicon etchant, one kind of the component (D) may be used alone, or two or more kinds thereof may be used in combination.

The upper limit value of the content of the component (D) is 1% by weight or less and preferably 0.5% by weight or less with respect to the total weight of the silicon etchant; the lower limit value thereof is 0% by weight or more, preferably 0.001% by weight or more, more preferably 0.01% by weight or more, and still more preferably 0.1% by weight or more, which is not limited thereto. In a case where the silicon etchant contains 0% by weight or more of the surfactant, which is the component (D), the contact angle and surface tension between the silicon etchant and the substrate can be effectively reduced, and thus the permeability in the silicon etching with respect to a narrow space having a high aspect ratio can be increased. However, the addition of the surfactant, which is the component (D), also drastically reduces the silicon etching rate at the same time. Therefore, in a case where the silicon etchant contains 1% by weight or less of the component (D), a good balance between high etching rate and the permeability can be achieved.

The silicon etchant of the present embodiment described above contains the component (A): a quaternary ammonium hydroxide such as tetramethylammonium hydroxide, the component (B): at least one or more amines selected from the group consisting of a specific polyamine and a specific alkanolamine, and the component (C): at least one or more solvents selected from the group consisting of water and a water-soluble organic solvent. Due to the combination of the above-described component (A), component (B), and component (C), an effect of a high silicon etching rate can be obtained even in a case where a small amount (for example, 2.38% by weight or less) of the component (A) is used.

Furthermore, due to the combination of the above-described component (A), component (B), component (C), and component (D) : a specific surfactant, a good balance between the high silicon etching rate and the excellent permeability (the low contact angle and low surface tension) with respect to a narrow space can be achieved, and thus an etching treatment can be carried out at a high silicon etching rate using the silicon etchant according to the present embodiment even in a case of a silicon substrate having a high aspect ratio (> 50 or more).

### Silicon Etching Method

A second aspect of the present invention is a silicon etching method of subjecting a silicon substrate having a silicon layer (an Si layer) with an aspect ratio of 50 or more to an etching treatment using the silicon etchant according to the first aspect described above.

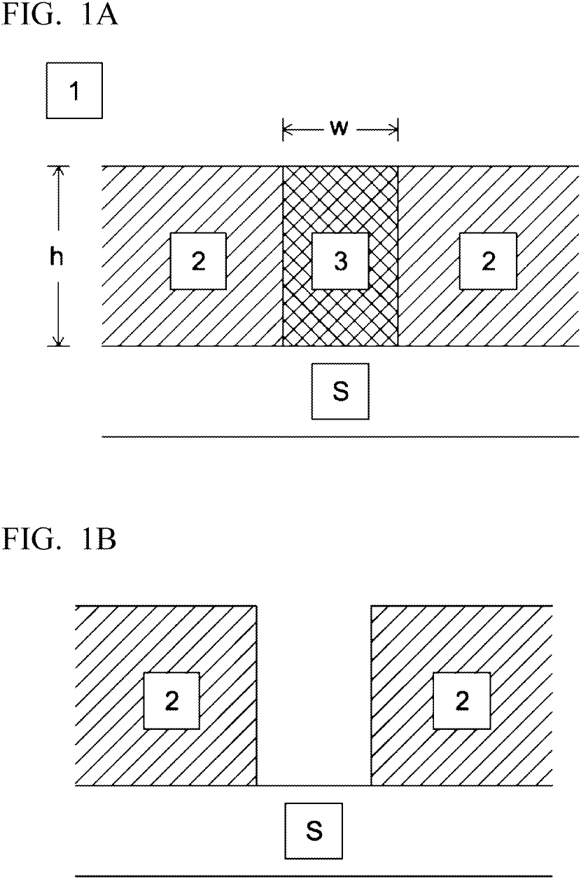

As shown in FIG. 1A, a silicon-on-insulator substrate (an SOI substrate) (1) before an etching treatment has a substrate (S) which is an insulating layer, a functional film layer (2) such as a silicon oxide film or a silicon nitride film, and a silicon layer (3). After the etching treatment, the silicon layer (3) is removed, and a pattern is formed, as shown in FIG. 1B.

In the above, the aspect ratio of the silicon layer (3) is indicated by the ratio (h/w) of the height (h) to the width (w) of the silicon layer (3), as shown in of FIG. 1A, and thus the aspect ratio of 50 or more means that the ratio of h/w is “50 or more/1”.

### [Etching Treatment]

Examples of the method of subjecting a silicon substrate to an etching treatment include a spray method, an immersion method, and a liquid puddle method.

The spray method is a method of transporting or rotating a silicon substrate in a predetermined direction, spraying the silicon etchant according to the first aspect in the space, and bringing the silicon etchant into contact with the silicon substrate. Further, the silicon etchant may be sprayed while the substrate rotates using a spin coater as necessary.

The immersion method is a method of immersing a silicon substrate in the silicon etchant according to the first aspect and bringing the silicon etchant into contact with the silicon substrate.

The liquid puddle method is a method of raising the silicon etchant according to the first aspect on a silicon substrate using the surface tension and maintaining the state for a certain period of time.

The various methods of carrying out an etching treatment can be appropriately selected according to the structure, the material, and the like of the silicon substrate. In a case of the spray method or the liquid puddle method, the amount of the silicon etchant according to the first aspect which is supplied to the silicon substrate may be an amount at which the surface of the silicon substrate to be treated is sufficiently wetted with the silicon etchant.

In a case of carrying out etching, the contact angle between the silicon etchant according to the first aspect and the silicon substrate is less than 35°. In addition, the surface tension between the silicon etchant according to the first aspect and the silicon substrate is less than 35 mN/m. The methods of measuring the contact angle and the surface tension are as described in Examples below.

In a case where the silicon etchant has such a low contact angle and low surface tension, it is possible to subject a silicon substrate to an etching treatment with the silicon etchant according to the first aspect described above, for example, even in a case where it is a silicon substrate having a silicon layer with an aspect ratio of 200 or more.

As described above, the silicon etchant according to the first aspect of the present invention is suitable for silicon substrates having a silicon layer with a high aspect ratio (> 50 or greater). However, those skilled in the art can understand naturally that it is possible to subject a silicon substrate to an etching treatment with the silicon etchant according to the first aspect of the present invention, for example, even in a case where it is a non-narrow silicon substrate having a silicon layer with a small aspect ratio (< 50).

The temperature at which the etching treatment is carried out is not particularly limited, and it is, for example, about 25° C. of room temperature; however, the etching treatment may be carried out under a heating condition. The time during which the etching treatment is carried out is not particularly limited, and it is, for example, 10 minutes or less, preferably 5 minutes or less, more preferably 3 minutes or less, particularly preferably 2 minutes or less, and most preferably within 1 minute. It is appropriately selected according to the structure and material of the silicon substrate and the etching conditions.

The silicon etching method of the present embodiment may include a washing step, a rinsing step, and a drying step in addition to the above-described etching treatment. The washing step and the rinsing step may be carried out before and after the etching treatment described above. The drying step may be carried out after the washing step and the rinsing step.

### [Washing Step]

The washing step is a step of washing the surface of the silicon substrate in advance.

The washing method is not particularly limited, and a known RCA washing method is exemplified as a method of washing a semiconductor substrate. In the RCA washing method, first, a substrate is immersed in a solution containing hydrogen peroxide and ammonium hydroxide, and fine particles and organic substances are removed from the substrate. Next, the substrate is immersed in a hydrofluoric acid aqueous solution so that a natural oxide film on the surface of the substrate is removed.

The rinsing step is a step of rinsing the surface of the silicon substrate with a rinsing liquid described later. The rinsing method is not particularly limited, and a method which has been generally used for washing a substrate in a semiconductor manufacturing step can be employed. Examples of such a method include a method of immersing a substrate in a rinsing liquid, a method of bringing the vapor of a rinsing liquid into contact with a substrate, and a method of supplying a rinsing liquid to a substrate while spinning the substrate. Among these, the method of supplying a rinsing liquid to a substrate while spinning the substrate is preferable as the rinsing method.

The rinsing liquid used in the rinsing step is not particularly limited, and a liquid which has been typically used for a rinsing step of a semiconductor substrate can be used. Examples of the rinsing liquid include those containing an organic solvent. Examples of the organic solvent include hydrocarbons, esters, ethers, ketones, halogen-containing solvents, sulfoxide-based solvents, alcohols, polyhydric alcohol derivatives, and nitrogen-containing compound solvents.

The drying step is a step of drying the silicon substrate. By carrying out the drying step, the rinsing liquid remaining on the silicon substrate after the rinsing step can be efficiently removed.

The method of drying the silicon substrate is not particularly limited, and a known method such as spin drying, heat drying, hot air drying, or vacuum drying can be used. Suitable examples thereof include spin drying under the condition of blowing inert gas (such as nitrogen gas).

According to the silicon etching method of the present embodiment described above, it is possible to subject a silicon substrate having a silicon layer with an aspect ratio of 50 or more to an etching treatment.

### EXAMPLES

Hereinafter, the present invention will be described in more detail based on examples, but the present invention is not limited to these examples.

### Preparation of Silicon Etchant

Each of components shown in Table 1 was mixed to prepare a silicon etchant of each example. It is noted that the total weight of the silicon etchant is 100% by mass with each of the components shown in Table .

TABLE 1

| | | | | |
|---|---|---|---|---|
| | Component A | Component B | Component C | Component D |
| Example1 | TMAH 2.38% | 13DAP 1% | Water 96.62% | - |
| Example 2 | TMAH 2.38% | 13DAP 2% | Water 95.62% | - |
| Example 3 | TMAH 2.38% | 13DAP 5% | Water 92.62% | - |
| Example 4 | TMAH 2.38% | 13DAP 10% | Water 87.62% | - |
| Example 5 | TMAH 2.38% | 13DAP 15% | Water 82.62% | - |
| Example 6 | TMAH 2.38% | 13DAP 20% | Water 77.62% | - |
| Example 7 | TMAH 2.38% | EDA 2% | Water 95.62% | - |
| Example 8 | TMAH 2.38% | 12DAP 2% | Water 95.62% | - |
| Example 9 | TMAH 2.38% | 14DAB 2% | Water 95.62% | - |
| Example 10 | TMAH 2.38% | DGA 2% | Water 95.62% | - |
| Example 11 | TMAH 2.38% | DIPA 2% | Water 95.62% | - |
| Example 12 | TMAH 2.38% | 13DAP 10% | Water 87.52% | A-32-Q 0.1% |
| Example 13 | TMAH 2.38% | 13DAP 10% | Water 87.12% | A-32-Q 0.5% |
| Example 14 | TMAH 2.38% | 13DAP 10% | Water 86.62% | A-32-Q 1% |
| Comparative Example 1 | TMAH 2.38% | - | Water 97.52% | A-32-Q 0.1% |
| Comparative Example2 | - | 13DAP 10% | Water 88.9% | A-32-Q 0.1% |

In Table 1, each abbreviation has the following meaning, and each of the corresponding component is commercially available.

TMAH: tetramethylammonium hydroxide (a 25% aqueous solution)

13DAP: 1,3-propanediamine (> 99% technical grade)

EDA: ethylenediamine (99% reagent grade)

12DAP: 1,2-propanediamine (> 98% reagent grade)

14DAB: 1,4-butanediamine (> 98% reagent grade)

DGA: 2-aminoethoxy)ethanol (98.5% electronics grade)

DIPA: diisopropanolamine (> 90% reagent grade)

AQ: trade name Takesurf-AQ (an anionic surfactant of an alkyl sulfonic acid salt; manufactured by TAKEMOTO OIL & FAT Co., Ltd.)

### Evaluation of Silicon Etching Rate

### · Regarding Object to Be Treated

An object to be treated is a polysilicon silicon-on-insulator (poly-SOI) wafer. The wafer was subjected to a pretreatment at 25° C. with a diluted hydrofluoric acid aqueous solution (1:100) for 90 seconds, rinsed with deionized water, and then dried under a nitrogen gas blow to remove the native oxide film on the wafer.

The wafer was cut into chips of about 1.5 cm × 1.5 cm, and ellipsometry (manufactured by Ellipso Technology Co., Ltd.; model number: Elli-SE-UaM12) was used to measure the thickness of the silicon layer of the chip before the etching treatment by an optical method.

### · Evaluation Method

The chip was immersed in the silicon etchant of each example and subjected to a silicon etching treatment at 25° C. After rinsing the chip after the silicon etching treatment with deionized water, the chip was dried under a nitrogen gas blow.

Then, the above ellipsometry was used to measure the thickness of the silicon layer of the chip after the etching treatment, by an optical method.

An average value of a value obtained according to “[(thickness of silicon layer after etching treatment) - (thickness of silicon layer before an etching treatment)]/(treatment time)” is defined as the silicon etching rate (the poly-Si etching rate).

### Evaluation of Contact Angle

### · Regarding Object to Be Treated

A polysilicon SOI wafer, which had been subjected to the same pretreatment as in [Evaluation of silicon etching rate], was prepared.

### · Evaluation Method

Using a fully automatic wafer contact angle meter (manufactured by Kyowa Co., Ltd.; model number: Dmo-701WA), the polysilicon SOI wafer which had been subjected to a pretreatment was set on a stage at room temperature. When a syringe on the instrument side is filled with the silicon etchant of each example, and the silicon etchant is manually added dropwise onto the wafer surface, a measurement is automatically carried out by the instrument to obtain a contact angle value (°).

### Evaluation of Surface Tension

### · Evaluation Method

Using a fully automatic wafer contact angle meter (manufactured by Kyowa Co., Ltd.; model number: Dmo-701WA), and a syringe on the instrument side was filled with the silicon etchant of each example at room temperature. When a liquid droplet having a predetermined size is dropped based on the instructions of the instrument, a measurement is automatically carried out by the instrument to obtain a surface tension value (mN/m).

Table 2 below shows the evaluation results of the silicon etching rate (poly-Si ER/25° C.), contact angle, and surface tension of each of the silicon etchants of Example 1 to Example 16 and Comparative Example 1 and Comparative Example 2.

TABLE 2

| | poly-Si ER (Å/min) | Contact angle (°) | Surface tension (mN/m) |
|---|---|---|---|
| Example 1 | 142 | > 50 | > 65 |
| Example 2 | 183 | > 50 | > 65 |
| Example 3 | 202 | > 50 | > 65 |
| Example 4 | 248 | > 50 | > 65 |
| Example 5 | 389 | > 50 | > 65 |
| Example 6 | 412 | > 50 | > 65 |
| Example 7 | 121 | > 50 | > 65 |
| Example 8 | 171 | > 50 | > 65 |
| Example 9 | 170 | > 50 | > 65 |
| Example 10 | 127 | > 50 | > 65 |
| Example 11 | 187 | > 50 | > 65 |
| Example 12 | 75 | < 35 | < 35 |
| Example 13 | 63 | < 35 | < 35 |
| Example 14 | 79 | < 35 | < 35 |
| Comparative Example 1 | 40 | < 35 | < 35 |
| Comparative Example2 | 36 | < 35 | < 35 |

From the results shown in Example 1 to Example 6 in Table 2, it can be seen that the silicon etching rate increases as the content of the component (B) increases. In addition, as a result of comparing Comparative Example 1 in which the component (B) was not added and Example 12 in which the component (B) was added, it can be seen that due to the combination of the component (A), the component (B), and the component (C), an effect of a high etching rate is obtained even with a small amount of the component (A).

In addition, from the results of Example 12 to Example 14, it can be seen that due to the combination of the component (A), the component (B), the component (C), and the (D) component, the excellent permeability with a low contact angle and low surface tension is obtained. Furthermore, as a result of being compared with Comparative Example 1 in which the component (B) was not added, it can be seen that from the increase in the etching rate of Example 12 to Example 14, an effect of a low surface tension and low contact angle with the substrate can be obtained together with a high etching rate.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

EXPLANATION OF REFERENCES
1: SOI substrate
2: Functional film layer
3: Silicon layer
S: Substrate

What is claimed is:

1. A silicon etchant, comprising:
a component (A): a quaternary ammonium hydroxide;
a component (B): an amine; and
a component (C): a solvent,
wherein the component (B) is at least one or more selected from the group consisting of a polyamine and an alkanolamine.

2. The silicon etchant according to claim 1, wherein the component (B) is at least one selected from the group consisting of 1,3-propanediamine, ethylenediamine, 1,2-propanediamine, 1,4-butanediamine, 2-(2-aminoethoxy)ethanol, and diisopropanolamine.

3. The silicon etchant according to claim 2, wherein the component (B) is 1,3-propanediamine or diisopropanolamine.

4. The silicon etchant according to claim 1, wherein the component (A) is tetramethylammonium hydroxide.

5. The silicon etchant according to claim 1, wherein the component (C) is at least one selected from the group consisting of water and a water-soluble organic solvent.

6. The silicon etchant according to claim 5, wherein the component (C) is water.

7. The silicon etchant according to claim 1, wherein a content of the component (A) is more than 0% by weight and 2.38% by weight or less with respect to a total weight of the silicon etchant.

8. The silicon etchant according to claim 1, wherein a content of the component (B) is more than 0% by weight and 30% by weight or less with respect to a total weight of the silicon etchant.

9. The silicon etchant according to claim 1, further comprising a surfactant component (D).

10. The silicon etchant according to claim 9, wherein a content of the component (D) is 0% by weight or more and 1% by weight or less with respect to a total weight of the silicon etchant.

11. The silicon etchant according to claim 9, wherein the component (D) is an anionic surfactant.

12. A silicon etching method comprising subjecting a silicon substrate having a silicon layer with an aspect ratio of 50 or more to an etching treatment using the silicon etchant according to claim 1.
